(19) United States
(12) Patent Application Publication
(10) Pub. No.: US 2014/0255286 A1
(43) Pub. Date: Sep. 11, 2014

(54) METHOD FOR MANUFACTURING CUBIC BORON NITRIDE THIN FILM WITH REDUCED COMPRESSIVE RESIDUAL STRESS AND CUBIC BORON NITRIDE THIN FILM MANUFACTURED USING THE SAME

(71) Applicant: KOREA INSTITUTE OF SCIENCE AND TECHNOLOGY, Seoul (KR)

(72) Inventors: Young Joon BAIK, Seoul (KR); Jong-Keuk PARK, Seoul (KR); Wook Seong LEE, Seoul (KR)

(73) Assignee: KOREA INSTITUTE OF SCIENCE AND TECHNOLOGY, Seoul (KR)

(21) Appl. No.: 13/903,309

(22) Filed: May 28, 2013

(30) Foreign Application Priority Data
Mar. 5, 2013 (KR) 10-2013-0023277

(51) Int. Cl. C23C 16/34

(52) U.S. Cl. CPC C23C 16/342
USPC 423/290; 427/523

(57) ABSTRACT

A method for manufacturing a cubic boron nitride (c-BN) thin film includes: applying a pulse-type bias voltage to a substrate; and forming the cubic boron nitride thin film by bombarding the substrate with ions using the pulse-type bias voltage. To control the compressive residual stress of the cubic boron nitride thin film, ON/OFF time ratio of the pulse-type bias voltage may be controlled. The compressive residual stress that is applied to the thin film can be minimized by using the pulse-type voltage as a negative bias voltage applied to the substrate. In addition, the deposition of the c-BN thin film can be performed in a low ion energy region by increasing the ion/neutral particle flux ratio through the control of the ON/OFF time ratio of the pulse-type voltage.

### CROSS-REFERENCE TO RELATED APPLICATION

This application claims priority to Korean Patent Application No. 10-2013-0023277, filed on Mar. 5, 2013, and all the benefits accruing therefrom under 35 U.S.C. §119, the contents of which in its entirety are herein incorporated by reference.

### BACKGROUND

1. Field

Exemplary embodiments relate to a method for manufacturing a cubic boron nitride (c-BN) thin film and a c-BN thin film manufactured using the same, and more particularly to a method for manufacturing a c-BN thin film having a strong adhesion caused by reducing the formation of a compressive residual stress which is applied to the c-BN thin film deposited by sputtering or the like.

2. Description of the Related Art

Cubic boron nitride (c-BN) has properties similar to those of diamond, which has extreme hardness and thermal conductivity. In addition, cubic boron nitride (c-BN) has excellent oxidation resistance, high-temperature stability and reaction stability for iron-based metals, compared to diamond. Thus, cubic boron nitride (c-BN) is highly applicable to abrasion-resistant thin films for cutting tools, molds and the like. A c-BN thin film can be deposited by various processes such as chemical vapor deposition (CVD) or physical vapor deposition (PVD). However, the c-BN thin film has not been applied due to its weak adhesion. The weak adhesion of the c-BN thin film is attributable to a compressive residual stress of about 10 GPa or higher, which is applied to an amorphous boron nitride (BN) layer and a turbostratic boron nitride (BN) layer, which are formed in the initial stage of the process for forming the c-BN thin film. In order to overcome this problem, efforts have been made to increase the adhesion of the c-BN thin film by reducing the compressive residual stress of the c-BN thin film or inserting an artificial intermediate layer into the c-BN thin film.

As a physical vapor deposition process for forming the c-BN thin film, an ion beam-assisted deposition (IBAD) process comprises generating boron and nitrogen elements with inert gas ions using an ion beam or an electron beam and allowing the generated boron and nitride elements to be incident on a substrate while irradiating the substrate with a separate ion beam. As another process, a sputtering process comprises applying high-frequency power to a boron nitride target to sputter boron (B) or nitrogen (N) atoms, and applying negative direct current power or high-frequency power to a substrate to bombard the substrate with ions to thereby form a thin film. It is experimentally known that hexagonal boron nitride (h-BN) is thermodynamically more stable than c-BN under general deposition conditions and that ion bombardment on a substrate during the deposition of a c-BN thin film is essential to synthesize a c-BN phase.

Typically, in various methods for depositing the c-BN thin film, argon (Ar) gas is used as an ion source, and ions that bombard a substrate are mainly argon (Ar) ions. Because the measurement and control of ion energy are easy in the IBAD method, many experimental studies have been conducted using the IBAD method. According to the results of the studies, it was reported that the synthesis of the c-BN thin film is determined by ion energy and the ratio of the flux of argon (Ar) ions to the flux of boron (B) atoms sputtered on a target.

FIG. 1 is a graph showing the synthesis region of each phase in a process for depositing the c-BN thin film by IBAD. In FIG. 1, the x-axis indicates ion energy, and the y-axis indicates the ratio of the flux of ions to the flux of neutral particles (i.e., boron atoms). As can be seen therein, ion energy and the ion/neutral particle flux ratio need to be at a certain level or higher in order to synthesize the c-BN phase. In addition, it can be seen that, as the ion/neutral particle flux ratio increases, ion energy required for the synthesis of c-BN decreases.

Meanwhile, the energy of ions bombarding the thin film has a close connection with the formation of compressive residual stress in the deposited c-BN thin film. As the ion energy increases, the degree of defects that are caused by the bombarded ions in the thin film increases, and residual stress that is applied to the film also increases due to argon (Ar) ions incorporated into the thin film. Thus, as the energy of ions that bombard the thin film becomes lower, the compressive residual stress of the thin film is likely to be reduced. For example, when the deposition conditions in FIG. 1 are moved in the direction of an arrow 100, the residual stress can be lowered because deposition occurs in the condition in which the energy of ions bombarding the thin film is low.

In the case of the IBAD process, when the ion sputtering rate on the boron nitride target by ions is reduced or the rate of volatilization of boron by an electron beam is reduced while the flux of argon (Ar) ions in an ion gun that makes argon (Ar) ions bombarding the substrate is increased, deposition conditions can be changed so as to reduce the energy of ions bombarding the thin film. However, in this case, there is a shortcoming in that the decrease in deposition rate is unavoidable. In addition, the IBAD process has various shortcomings in terms of the actual application thereof, and thus has not been applied to a general production process.

A PVD process that is used for coating of a cutting tool and the like is generally a sputtering process. This is because the sputtering process easily performs large-area deposition and has a relatively high deposition rate. When a BN film is to be deposited by the sputtering process, high-frequency power is applied to an h-BN target to ionize argon (Ar) atoms in a vacuum chamber, and then the boron (B) and nitrogen (N) atoms of the target are sputtered in a vapor phase using the ions. Then, the sputtered atoms are moved to and deposited on a substrate. Herein, plasma consisting mainly of argon (Ar) ions and electrons is present between the target and the substrate and supplies argon (Ar) ions that are used to sputter the target or bombard the substrate. When the film is formed by the sputtered atoms, a negative bias voltage is applied to induce the bombardment of argon (Ar) ions on the substrate.

In the sputtering process, ions that generate boron (B) and nitrogen (N) atoms as deposition sources, and ions that bombard the substrate are argon (Ar) ions supplied by the same plasma, unlike the above-described IBAD process. Moreover, plasma is generated by power applied to the target. Thus, when the level of power applied is increased, the concentration of argon (Ar) ions will increase, and as a result, the concentration of the boron (B) and nitrogen (N) sputtered on the target will also increase. Due to this relationship between the concentration of argon (Ar) ions and the concentration of sputtered neutral particles, it is difficult in the case of sputtering to control the ratio of the flux of argon (Ar) ions relative to the flux of boron (B) atoms.

Meanwhile, when the film to be synthesized in the sputtering process is not electrically conductive, a high-frequency power source can be used as a power source for applying a negative bias voltage to the substrate in order to prevent an arc from occurring due to the discharge of cumulative charges. Herein, power that is applied to the substrate is referred to as a self-bias voltage. As shown in FIG. 1, a critical ion energy is required to synthesize c-BN at a specific ion/boron atom flux ratio. In other words, the bombardment of ions having energy equal to or higher than the critical energy is required to make the deposition of the c-BN phase possible. Meanwhile, as the energy of ions increases, the compressive residual stress of the thin film increases. For this reason, it is advantageous that the energy of all bombarding ions is near the critical energy in order to reduce the residual stress. However, when bias power is applied using a high-frequency power source, most ions will have energy significantly higher than the critical energy due to the characteristics of alternating current waveforms. Thus, the use of self-bias caused by a high-frequency power source is not preferable in terms of residual stress.

### SUMMARY

In accordance with an aspect of the present disclosure, there may be provided a method for manufacturing a cubic boron nitride (c-BN) thin film, which can reduce the energy of ions bombarding a substrate during a process of depositing the c-BN thin film by a sputtering process or the like and can reduce the compressive residual stress of the thin film, and a c-BN thin film manufactured using the method.

A method for manufacturing a cubic boron nitride (c-BN) thin film according to an embodiment may include: applying a pulse-type bias voltage to a substrate; and forming the c-BN thin film by bombarding the substrate with ions using the pulse-type bias voltage.

In order to control the compressive residual stress of the c-BN thin film, the ON/OFF time ratio of the pulse-type bias voltage may be controlled. For example, the time ratio of the ON period of the pulse-type bias voltage to the OFF period may be increased to 5 or more.

The c-BN thin film may be manufactured by a sputtering process or a plasma-assisted chemical vapor deposition process. For example, forming the c-BN thin film may include allowing boron particles and nitrogen particles to be incident on the substrate; and bombarding the substrate with ions accelerated by the pulse-type bias voltage. Herein, the ions may be argon ions.

The pulse-type bias voltage may be a direct current pulse voltage or an alternating current pulse voltage. In addition, the pulse-type bias voltage may also be a unipolar voltage or a bipolar voltage.

A c-BN thin film according to an embodiment may be manufactured by the above-described method for manufacturing the c-BN thin film.

### BRIEF DESCRIPTION OF THE DRAWINGS

FIG. 1 is a graph showing the synthesis region of each phase in a process for depositing a cubic boron nitride (c-BN) thin film by ion beam-assisted deposition (IBAD).

FIG. 2 schematically shows a high-frequency voltage waveform and a pulse-type voltage waveform, which can be used in a process for depositing a c-BN thin film.

FIG. 3 shows the Fourier transform infrared spectrum of a thin film as a function of the ON/OFF time ratio of a pulse-type bias voltage applied to a substrate.

FIG. 4 shows a parameter space map for the phase formation of a thin film as a function of the magnitude and ON/OFF time ratio of a pulse-type bias voltage applied to a substrate.

FIG. 5 shows the change in the compressive residual stress of a thin film as a function of the magnitude and ON/OFF time ratio of a pulse-type bias voltage applied to a substrate.

FIG. 6 shows the change in the thickness of a thin film as a function of the magnitude and ON/OFF time ratio of a pulse-type bias voltage applied to a substrate.

### DETAILED DESCRIPTION

Hereinafter, exemplary embodiments of the present invention will be described in further detail with reference to the accompanying drawings.

Embodiments are directed to a method for manufacturing a cubic boron nitride (c-BN) thin film by forming a cubic phase in the synthesis of a boron nitride (BN) thin film and to a c-BN thin film manufactured using the method. Embodiments are based on a deposition process in which boron (B) and nitrogen (N) atoms are allowed to be incident on a substrate, on which a thin film is to be formed, while the substrate is bombarded with argon (Ar) ions, thereby forming the thin film. Herein, the argon (Ar) ions are attracted to the substrate by a bias voltage applied to the substrate. In the method for forming the c-BN thin film according to embodiments, the c-BN thin film can be formed by an unbalanced magnetron (UBM) sputtering process or other sputtering processes.

However, these embodiments are only illustrative, and in other embodiments, the c-BN thin film may also be formed by other different physical vapor deposition (PVD) processes capable of forming the c-BN thin film while bombarding a substrate with ions by a bias voltage applied to the substrate. In addition, the c-BN thin film may also be formed by plasma-assisted CVD processes such as electron cyclotron resonance (ECR) plasma-assisted chemical vapor deposition (CVD), or other CVD processes.

Embodiments are configured to reduce the compressive residual stress of the c-BN thin film by reducing the energy of argon (Ar) ions required for the formation of the c-BN phase. For this purpose, in the method for preparing the c-BN thin film according to the embodiments, a negative bias voltage is applied to the substrate. The negative bias voltage may have a pulse-type waveform. In addition, the ratio of the flux of ions to the flux of boron (B) atoms that are neutral particles having no electric charge can be controlled by controlling the ratio of a time period, during which the pulse-type bias voltage is applied, to a time period during which the pulse-type bias voltage is not applied, that is, the ON/OFF time ratio. This will be described in detail below.

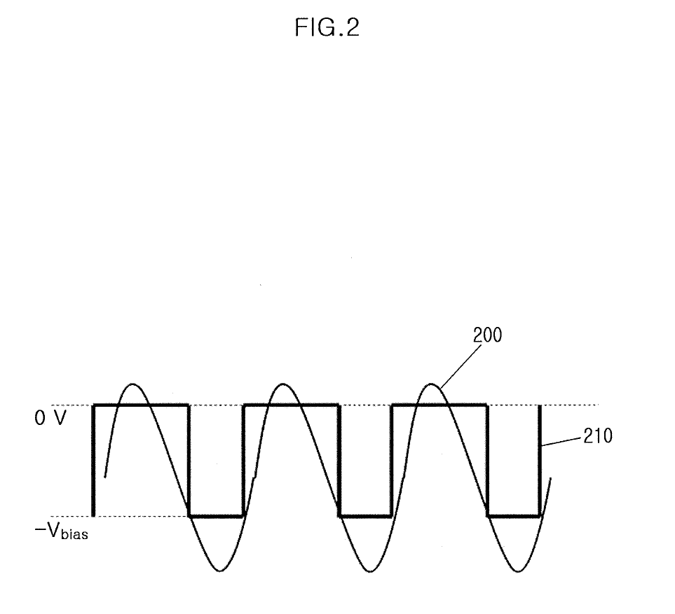

FIG. 2 schematically shows a high-frequency voltage waveform 200, which is used in a conventional process for depositing a c-BN thin film, and a pulse-type bias voltage waveform 210 which is used in a method for manufacturing a c-BN thin film according to an embodiment.

Referring to FIG. 2, in order to form a c-BN phase at a given ion/boron atom flux ratio, a voltage equal to or lower than a predetermined critical negative voltage (−V_{bias}) should be applied to a substrate. However, due to the characteristic of an alternating voltage whose magnitude changes periodically, the substrate self-bias by the conventional high-frequency voltage 200 includes a region where the absolute voltage value is greater than the above-described critical negative voltage (−V_{bias}) to form the c-BN phase. In this case, a variable voltage that changes periodically is applied to the substrate, and thus the energy of ions that bombard the substrate is also variable. Accordingly, ions can bombard the substrate in a state in which they have energy greater than the critical energy for forming the c-BN phase, resulting in an increase in the compressive residual stress of the deposited c-BN thin film.

On the other hand, the bias voltage 210 in embodiments of the present disclosure may have a pulse-type waveform that has the critical negative voltage (−V_{bias}), which is to be applied to the substrate in order to form the c-BN phase at a given ion/boron atom flux ratio, as a low value, and has 0 as a high value. When the pulse-type bias voltage 210 is used, the energy of ions that bombard the substrate during the deposition of the c-BN thin film can be reduced by the following two principles, and thus the energy of ions can be maintained at a low level.

First, the pulse-type bias voltage 210 has, as an ON period value, the critical negative voltage (−V_{bias}), which is to be applied to the substrate in order to form the c-BN phase at a specific ion/boron atom flux ratio, or a voltage near the same. The energy of ions that bombard the substrate is determined by a voltage applied to the substrate to accelerate ions. Thus, when the pulse-type bias voltage 210 is applied to the substrate, the bombardment of ions, which have energy equal or higher than a desired self-bias voltage, on the substrate, can be reduced or prevented. As a result, the increase of the compressive residual stress of the c-BN thin film due to the bombardment of ions having high energy can be prevented.

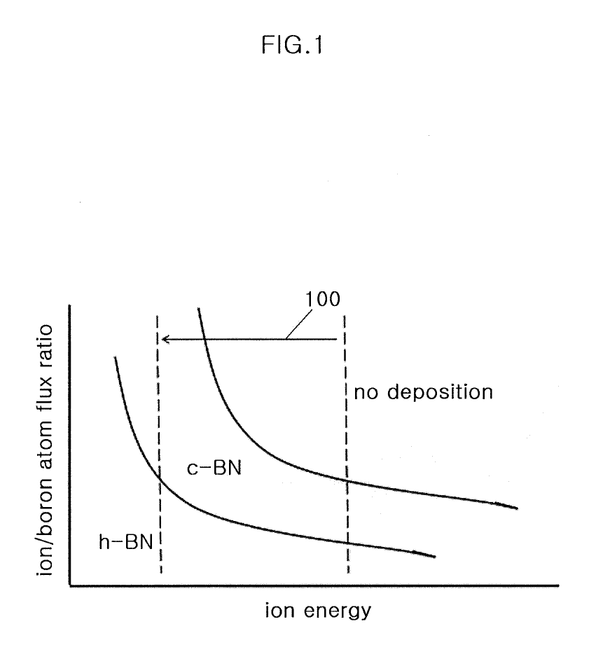

Second, the use of the pulse-type bias voltage 210 makes it possible to control the time ratio of an ON period, during which the voltage is applied to the substrate, relative to an OFF period during which the voltage is not applied to the substrate. When the voltage that is applied in the ON period is set at a value equal to or smaller than the critical negative voltage (−V_{bias}) required for the formation of c-BN, the flux of ions acting on the formation of c-BN is determined according to the length of the ON period. Meanwhile, boron (B) and nitrogen (N), which participate in deposition, have no electric charge. Thus, the flux of boron (B) and nitrogen (N) atoms is determined only by power applied to the target rather than the substrate and has no concern with the ON period and OFF period of the bias voltage applied to the substrate. Thus, the ratio of the flux of ions to the flux of neutral particles can be controlled by controlling the ratio of the ON period to the OFF period of the pulse-type bias voltage 210. As described above with reference to FIG. 1, when the ion/neutral particle flux ratio is controlled, the c-BN thin film can be deposited at low ion energy, and as a result, the compressive residual stress of the thin film can be reduced.

Thus, when the pulse-type bias voltage 210 is applied to the substrate during the deposition of the c-BN thin film according to this embodiment, the dispersion of ion energy, which occurs when using the high-frequency voltage 200 as a bias voltage in the conventional process, can be minimized. Further, the deposition of the c-BN thin film can be performed in a low ion energy region.

In the embodiment shown in FIG. 2, the pulse-type bias voltage 210 is a direct current pulse voltage which is constant throughout the region. However, this is only illustrative, and in other embodiments, the pulse-type bias voltage may also be an alternating current pulse voltage whose magnitude increases or decreases in a sine waveform throughout the region. Moreover, in the embodiment shown in FIG. 2, the pulse-type bias voltage 210 is a unipolar voltage whose magnitude changes between 0 and a specific negative value. However, this is only illustrative, and in other embodiments, the pulse-type bias voltage may also be a bipolar voltage whose magnitude changes between a specific positive value and a specific negative value. For example, when an arc is likely to occur in the deposited film, the bias voltage may be configured as a bipolar direct current pulse or alternating current pulse form to prevent the arc from occurring.

The method for preparing the c-BN thin film according to the above-described embodiments is based on a sputtering process which is widely used in a coating process for mass production, and thus, it can be easily used as a commercial process. In addition, because the pulse-type bias voltage is used, the compressive residual stress of the c-BN thin film can be greatly reduced to improve the adhesion of the thin film, and thus the c-BN thin film can be easily used for abrasion-resistant applications.

Hereinafter, the method for preparing the c-BN thin film according to an embodiment of the present disclosure and the properties of the c-BN thin film manufactured using the method will be described in detail with reference to examples.

In an embodiment, a c-BN thin film was deposited on a silicon (Si) substrate using a UBM sputtering process. As a target, hexagonal boron nitride (BN) having a diameter of about 5 cm was used. The target was connected to a high-frequency power source having a power of about 400 W and a frequency of about 13.56 MHz. The silicon (Si) substrate was placed on a molybdenum (Mo) support having a diameter of about 10 cm. In order to apply a negative bias voltage to the substrate, a direct current pulse power source having a frequency of about 10 KHz was connected to the substrate support, and a voltage of about −150 V was applied. The reaction chamber was exhausted to a pressure of about 10⁻⁶ mtorr or less, and an argon (Ar)/nitrogen (N₂) gas mixture containing about 10 vol % of nitrogen was supplied into the chamber so as to maintain a pressure of about 2 mtorr. The silicon substrate was cleaned with a general organic solvent, and then mounted into the chamber. Deposition was performed for about 15 minutes, while the ON/OFF time ratio of the pulse-type bias voltage was changed in the range from 1 to 10.

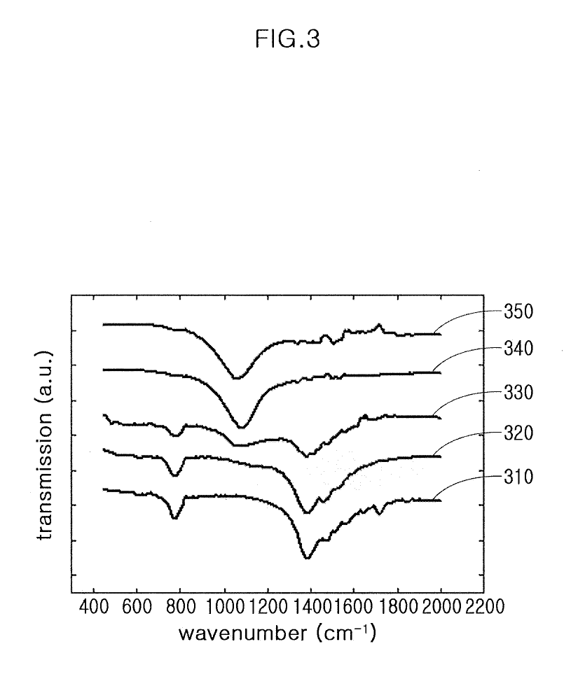

FIG. 3 is a graphic diagram showing the Fourier transform infrared (FTIR) spectrum of the thin film formed under the above-described experimental conditions. The five graphs 310, 320, 330, 340 and 350 shown in FIG. 3 correspond to the boron nitride thin films manufactured when the ON/OFF time ratios of the pulse-type bias voltage were set at 1, 3, 5, 7 and 10, respectively. It is known that the hexagonal boron nitride (h-BN) phase shows absorption peaks at around 780 cm⁻¹ and 1380 cm⁻¹ in the FTIR spectrum and the c-BN shows an absorption peak at around 1080 cm⁻¹. Referring to FIG. 3, the peak corresponding to the c-BN phase was detected at an ON/OFF time ratio of 5 or greater. Thus, in an embodiment, the ON/OFF time ratio of the pulse-type bias voltage can be controlled to 5 or greater in order to form the c-BN thin film.

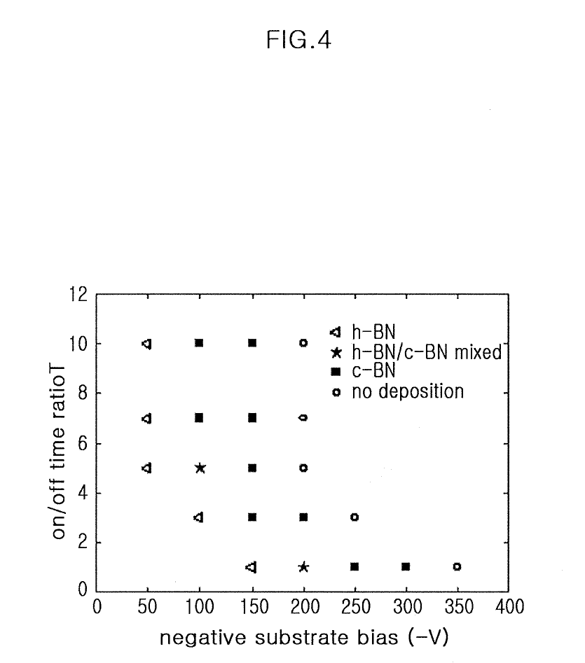

FIG. 4 shows a parameter space map constructed based on the results of FTIR analysis of the specimens deposited in the above-described example with reference to FIG. 3.

In FIG. 4, the x-axis indicates the pulse-type bias voltage applied to the substrate, and the y-axis indicates the ON/OFF time ratio of the pulse-type bias voltage. As shown therein, the parameter space showing the results of formation of the boron nitride film is divided into a h-BN formation region, a c-BN formation region and a region in which no deposition occurred. As can be seen therein, as the ON/OFF time ratio of the pulse-type bias voltage increased, the absolute value of the bias voltage required for c-BN formation decreased.

When comparing FIG. 4 with FIG. 1 showing the parameter space map obtained by the ion beam assisted deposition (IBAD) process, it can be seen that the c-BN formation region has a behavior similar to that shown in FIG. 1. Thus, it can be seen that changing the ON/OFF time ratio of the pulse-type bias voltage has an effect similar to an effect obtained when changing the ion/neutral particle flux ratio in FIG. 1. Thus, when the ON/OFF time ratio of the pulse-type bias voltage is increased, the c-BN thin film can be deposited at a low absolute voltage value, and as a result, the compressive residual stress of the c-BN thin film can be reduced.

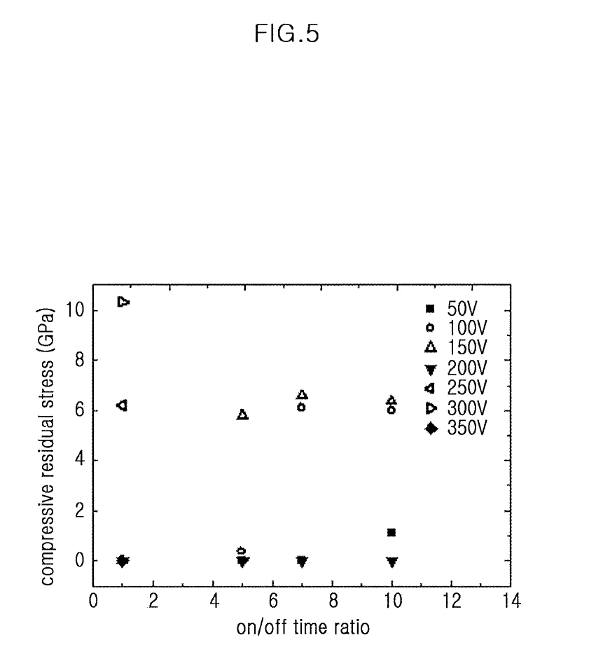

FIG. 5 shows the results of measurement of the change in the compressive residual stress of the thin film, prepared in the above-described example with reference to FIGS. 3 and 4, as a function of the magnitude and ON/OFF time ratio of the pulse-type bias voltage.

As can be seen in FIG. 5, when the ON/OFF time ratio of the pulse-type bias voltage in the c-BN formation region is constant, the compressive residual stress of the thin film increases as the absolute voltage value increases, but the magnitude of the compressive residual stress decreases as the ON/OFF time ratio increases. This is believed to be because deposition is possible even by a bias voltage whose absolute value is small, when the ON/OFF time ratio is high. Thus, when a pulse-type voltage is used as the bias voltage of the substrate and deposition is performed at a high ON/OFF time ratio, a thin film having a low compressive residual stress can be formed while maintaining the c-BN phase.

For example, as can be seen in FIG. 5, when the ON/OFF time ratio of the to pulse-type bias voltage is set at 1, the c-BN phase is formed when the absolute value of the bias voltage is 250 V or higher. Also, when the absolute value of the bias voltage is 300 V, the compressive residual stress is measured to be about 11 GPa. On the other hand, when the ON/OFF time ratio of the pulse-type bias voltage is increased to 10, the c-BN phase can be synthesized when the absolute value of the bias voltage is as low as 100 V, and in this case, the compressive residual stress decreases to about 7 GPa. Thus, it can be seen that the compressive residual stress of the c-BN thin film can be effectively reduced by increasing the ON/OFF time ratio of the pulse-type bias voltage.

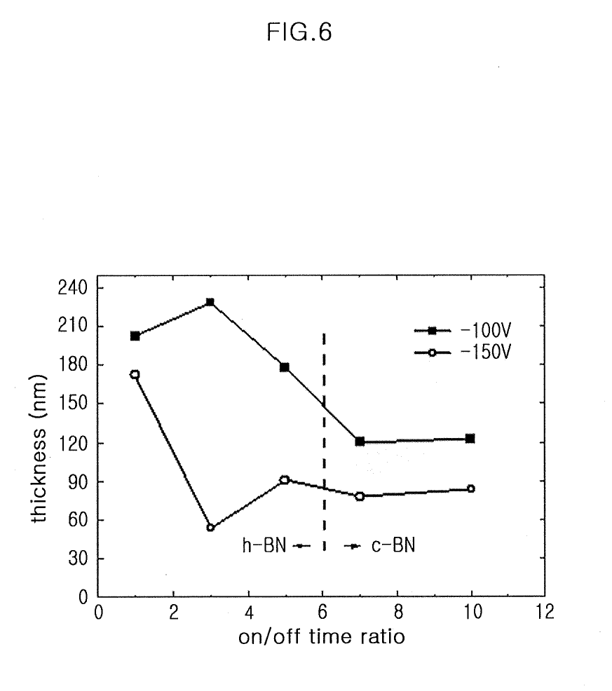

Meanwhile, the deposition rate of thin films has a direct connection with the price of the product in a mass production process. Thus, if the deposition rate decreases even though the compressive residual stress decreases, the application of the process will be difficult. In order to confirm this fact, the thicknesses of the thin films prepared in the above-described examples were measured, and the results of the measurement are shown in FIG. 6.

FIG. 6 shows the thickness of the BN thin films, deposited for about 15 minutes, as a function of the magnitude and ON/OFF time ratio of the pulse-type bias voltage applied to the substrate. As can be seen therein, the change in the thickness of the thin film in the region in which the c-BN phase is formed is not significant. In addition, it can be seen that the thickness of the thin film increases as the absolute value of the bias voltage decreases. Thus, it can be seen that, when the pulse-type bias voltage is used, the decrease in the growth rate of the c-BN thin film is not significant. Rather, the decreased absolute value of the bias voltage required for the c-BN phase provides the effect of increasing the thickness of the thin film. In other words, it is confirmed that, when the pulse-type bias voltage is used and the ON/OFF time ratio thereof is increased, the effects of reducing the compressive residual stress and increasing the deposition rate can be obtained without having adverse effects on the deposition behavior of the c-BN thin film.

As described above, in the method for manufacturing the cubic boron nitride (c-BN) thin film according to embodiments, the compressive residual stress that is applied to the thin film can be reduced by using a pulse-type voltage as a negative bias voltage which is applied to a substrate during a process of depositing the c-BN thin film by a sputtering process or the like. When the ratio of the flux of ions to the flux of neutral particles is controlled by controlling the ON/OFF time ratio of the pulse-type voltage so that c-BN is formed at a high ion/neutral particle flux ratio, deposition can be performed in a low ion energy region. The above-described method for manufacturing the c-BN thin film is based on a sputtering process, and thus can be easily used in general coating processes. In addition, according to the above method, the adhesion of the c-BN thin film can be improved by greatly reducing the compressive residual stress of the thin film, and thus the c-BN thin film can be easily used for abrasion-resistant applications.

Although the present invention has been described with reference to the embodiments shown in the drawings, these embodiments are illustrative only and those skilled in the art will appreciate that various modifications, additions and substitutions are possible, without departing from the technical protection scope of the present invention. Therefore, the true technical protection scope of the present invention should be defined by the technical spirit of the appended claims.

What is claimed is:

1. A method for manufacturing a cubic boron nitride thin film, the method comprising:
applying a pulse-type bias voltage to a substrate; and
forming the cubic boron nitride thin film by bombarding the substrate with ions using the pulse-type bias voltage.

2. The method of claim 1, further comprising controlling an ON/OFF time ratio of the pulse-type bias voltage to control the compressive residual stress of the cubic boron nitride thin film.

3. The method of claim 2, wherein controlling the ON/OFF time ratio of the pulse-type bias voltage comprises increasing a time ratio of an ON period of the pulse-type bias voltage relative to an OFF period to 5 or greater.

4. The method of claim 1, wherein forming the cubic boron nitride thin film is performed by a sputtering process or a chemical vapor deposition process.

5. The method of claim 1, wherein forming the cubic boron nitride thin film comprises:
allowing boron and nitrogen atoms to be incident on the substrate; and
bombarding the substrate with ions accelerated by the pulse-type bias voltage.

6. The method of claim 5, wherein the ions are argon ions.

7. The method of claim 1, wherein the pulse-type bias voltage is a direct current pulse voltage or an alternating current pulse voltage.

8. The method of claim 1, wherein the pulse-type bias voltage is a unipolar voltage or a bipolar voltage.

9. A cubic boron nitride thin film disposited on a substrate, the cubic boron nitride thin film manufactured by a process comprising:
applying a pulse-type bias voltage to the substrate; and
forming the cubic boron nitride thin film by bombarding the substrate with ions using the pulse-type bias voltage.

10. The cubic boron nitride thin film of claim 9, wherein the pulse-type bias voltage is a direct current pulse voltage or an alternating current pulse voltage.

11. The cubic boron nitride thin film of claim 9, wherein the pulse-type bias voltage is a unipolar voltage or a bipolar voltage.
